(19) United States
(12) Patent Application Publication
(10) Pub. No.: US 2016/0197057 A1
(43) Pub. Date: Jul. 7, 2016

(54) SEMICONDUCTOR PACKAGES

(71) Applicant: Samsung Electronics Co., Ltd., Suwon-si (KR)

(72) Inventors: Mitsuo Umemoto, Seongnam-s i (KR); Donghan Kim, Osan-si (KR); Jae Choon Kim, Incheon (KR); Jikho Song, Seoul (KR); Inho Choi, Seoul (KR)

(21) Appl. No.: 14/955,516

(22) Filed: Dec. 1, 2015

(30) Foreign Application Priority Data
Jan. 2, 2015 (KR) 10-2015-0000065

(51) Int. Cl. H01L 25/065; H01L 23/31; H01L 23/00; H01L 23/498

(52) U.S. Cl. CPC H01L 25/0657; H01L 23/49838; H01L 23/3171; H01L 24/09; H01L 24/08; H01L 25/0652; H01L 23/49866; H01L 24/17; H01L 23/3192; H01L 2225/06551; H01L 2225/06513; H01L 2224/02373; H01L 2224/02381; H01L 2224/0401; H01L 2224/08148; H01L 2224/08238; H01L 2224/16104; H01L 2224/16113; H01L 2224/16148; H01L 2224/16227; H01L 2224/16238; H01L 2924/1579; H01L 2924/15747

(57) ABSTRACT

The invention relates to a semiconductor package that includes a connection member disposed at one side of the semiconductor chip, an insulating layer covering bottom surfaces of the semiconductor chip and the connection member, a molding layer that is disposed on the insulating layer and covers a side surface of the semiconductor chip and a top surface and opposing side surfaces of the connection member, an electric line disposed on the insulating layer and electrically connected to the semiconductor chip and the connection member, and an external terminal disposed on the insulating layer and electrically connected to the electric line.

### CROSS-REFERENCE TO RELATED APPLICATIONS

This U.S. nonprovisional patent application claims priority under 35 U.S.C. §119 of Korean Patent Application 10-2015-0000065 filed on Jan. 2, 2015, the entire contents of which are hereby incorporated by reference.

### BACKGROUND

The present inventive concept relates to a semiconductor package and, more particularly, to a fan-out wafer level semiconductor package.

As the electronics industry has developed in recent years, semiconductor packages have evolved in various directions aiming for improvements in compactness, lighter weight and cost reduction. Moreover, the types of semiconductor packages have also diversified to better meet the particular needs of a variety of applications, for example in MP3 players, mobile phones, high capacity memory apparatus, and so forth. Thus, today there are many kinds of semiconductor packages, for example, a ball grid array (BGA) package and a wafer-level package.

The wafer-level package is fabricated by forming redistribution patterns on a semiconductor chip without a molding process and then attaching solder balls onto the redistribution patterns. Because a process for fabricating the wafer level package does not require the molding step and an integrated circuit board, it is possible to reduce the thickness of the wafer level package.

As the trends continue toward increasingly high integration of the semiconductor chip, the size of the semiconductor chip needs to become smaller. The wafer level package, however, has disadvantages because of adhesion of the solder balls and because the pitch or spacings between solder balls are settled according to a worldwide standard (e.g., JEDEC). There are also disadvantages in handling such a structure due to its small size.

Fan-out wafer level packages have been developed to address these disadvantages. In a process for fabricating the fan-out wafer level packages, a molding layer is provided around the semiconductor chip and the redistribution pattern is formed on a bottom side of the molding layer to which the solder balls are attached.

### SUMMARY

Embodiments of the inventive concept provide a semiconductor package having an enhanced reliability.

According to an exemplary embodiment of the present inventive concept, a semiconductor package comprising: a first semiconductor chip; a connection member disposed at one side of the first semiconductor chip; a first insulating layer covering bottom surfaces of the first semiconductor chip and the connection member; a first molding layer that is disposed on the first insulating layer and covers a side surface of the first semiconductor chip and a top surface and opposite side surfaces of the connection member; a first electric line disposed on the first insulating layer and electrically connected to the first semiconductor chip and the connection member; and an external terminal disposed on the first insulating layer and electrically connected to the first electric line.

In some embodiments, the top surface of the first semiconductor chip is exposed from the first molding layer.

In some embodiments, the top surface of the first semiconductor chip has a level substantially the same as a top surface of the first molding layer.

In some embodiments, the connection member comprises a body portion and a conductive connector penetrating the body portion, and the conductive connector contacts the first electric line.

In some embodiments, a first chip pad is disposed on the bottom surface of the first semiconductor chip; and a resist layer covers the bottom surface of the first semiconductor chip and exposes the first chip pad, and the first chip pad contacts the first electric line.

In some embodiments, a second insulating layer is disposed on a top surface of the first semiconductor chip; and a second electric line is disposed in the second insulating layer and electrically connected to the connection member, and the second insulating layer contacts top surfaces of the first semiconductor chip and the first molding layer.

In some embodiments, a second semiconductor chip is disposed on the second insulating layer; a second chip pad is disposed on a bottom surface of the second semiconductor chip; a solder ball is adhered to the second chip pad and electrically connected to the second electric line; and a second molding layer is disposed on the second insulating layer and covers the second semiconductor chip.

In some embodiments, the external terminal is disposed between the first semiconductor chip and the connection member.

In another aspect, embodiments of this invention comprise a lower semiconductor chip; a connection member disposed at one side of the lower semiconductor chip; a lower insulating layer covering bottom surfaces of the lower semiconductor chip and the connection member; a lower molding layer that is disposed on the lower insulating layer and covers the connection member; a lower electric line disposed in the lower insulating layer and electrically connected to the lower semiconductor chip and the connection member; an upper insulating layer disposed on the molding layer and contacting a top surface of the lower semiconductor chip; an upper electric line disposed in the upper insulating layer and electrically connected to the connection member; and an external terminal disposed on the lower insulating layer and electrically connected to the lower electric line.

In some embodiments, the lower semiconductor chip and the connection member have the same thickness such that a top surface of the connection member contacts the upper insulating layer.

In some embodiments, the lower semiconductor chip has a thickness greater than that of the connection member.

In some embodiments, the lower molding layer is interposed between the upper insulating layer and the connection member, and the lower molding layer on the connection member contacts a bottom surface of the upper insulating layer and a top surface of the connection member.

In some embodiments, the lower molding layer has a thickness substantially the same as that of the lower semiconductor chip.

In some embodiments, the lower semiconductor chip has a thickness greater than that of the connection member such that a top surface of the molding layer is higher than a top surface of the connection member.

In some embodiments, an upper semiconductor chip is mounted on the upper insulating layer; and an upper molding layer is disposed on the upper insulating layer and covers the upper semiconductor chip.

In another aspect, embodiments of this invention comprise a semiconductor package that includes a lower semiconductor chip; a connection member at one side of the lower semiconductor chip; a lower insulating layer covering bottom surfaces of the lower semiconductor chip and the connection member; a lower molding layer that is on the lower insulating layer and covers the connection member; a lower electric line in the lower insulating layer and electrically connected to the lower semiconductor chip and the connection member; an upper insulating layer on a top surface of the lower semiconductor chip; an upper electric line disposed in the upper insulating layer and electrically connected to the connection member; an external terminal on the lower insulating layer and electrically connected to the lower electric line; and an upper semiconductor chip electrically connected to the upper electric line to provide an electrical connection between the upper and the lower semiconductor chips via the connection member.

In some embodiments of this aspect, the lower semiconductor chip and the connection member have the same thickness such that a top surface of the connection member contacts the upper insulating layer.

In some embodiments of this aspect, the lower semiconductor chip has a thickness greater than that of the connection member.

In some embodiments of this aspect, the connection member comprises a body portion and a conductive connector disposed in the body portion, and the conductive connector is electrically connected to the lower electric line and the upper electric line.

In some embodiments of this aspect, the body portion is consisting of a copper clad laminate.

### BRIEF DESCRIPTION OF THE DRAWINGS

The foregoing and other features and advantages of exemplary embodiments of inventive concepts will be apparent from the more particular description of non-limiting embodiments of inventive concepts, as illustrated in the accompanying drawings in which like reference characters refer to the same parts throughout the different views. The drawings are not necessarily to scale, emphasis instead being placed upon illustrating the principles of inventive concepts. In the drawings:

FIG. 1 illustrates a schematic plan view of semiconductor chips arranged on a support substrate;

FIG. 2 illustrates a schematic cross-sectional view of a semiconductor package according to an exemplary embodiment of the present inventive concept;

FIG. 3 illustrates a schematic cross-sectional view of a semiconductor package according to another exemplary embodiment of the present inventive concept;

FIGS. 4A to 4H illustrate schematic cross-sectional views of sequential process steps in a method for fabricating a semiconductor package according to an exemplary embodiment of the present inventive concept;

FIG. 5 illustrates a block diagram of an example of an electronic device that includes a semiconductor package according to an exemplary embodiment; and

FIG. 6 illustrates a block diagram of an example of a memory system that includes a semiconductor package according to an exemplary embodiment.

### DETAILED DESCRIPTION OF EXEMPLARY EMBODIMENTS

Exemplary embodiments of the inventive concepts will now be described more fully hereinafter with reference to the accompanying drawings, in which some exemplary embodiments of inventive concepts are shown. Exemplary embodiments may, however, be embodied in many different forms and should not be construed as being limited to the embodiments set forth herein. Rather, these exemplary embodiments are provided so that this disclosure will be thorough and complete, and will fully convey the scope of exemplary embodiments of the inventive concepts to those of ordinary skill in the art. In the drawings, the thicknesses of layers and regions are exaggerated for clarity. Like reference numerals in the drawings denote like elements. Hereinafter, exemplary embodiments of the present invention will be more fully described in conjunction with the accompanying drawings.

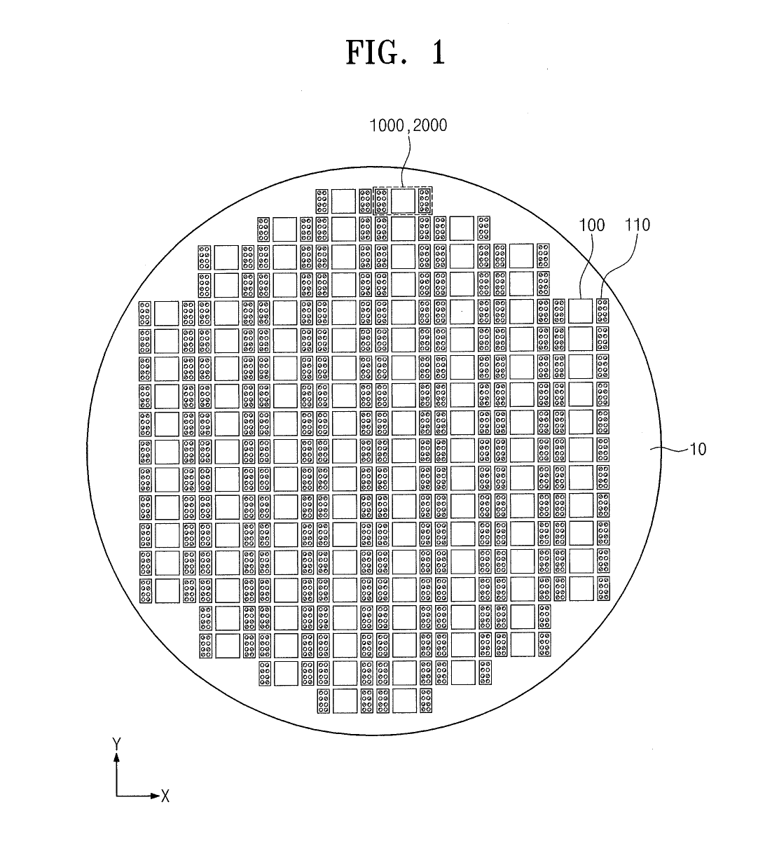

FIG. 1 illustrates a plan view of semiconductor chips arranged on a support substrate.

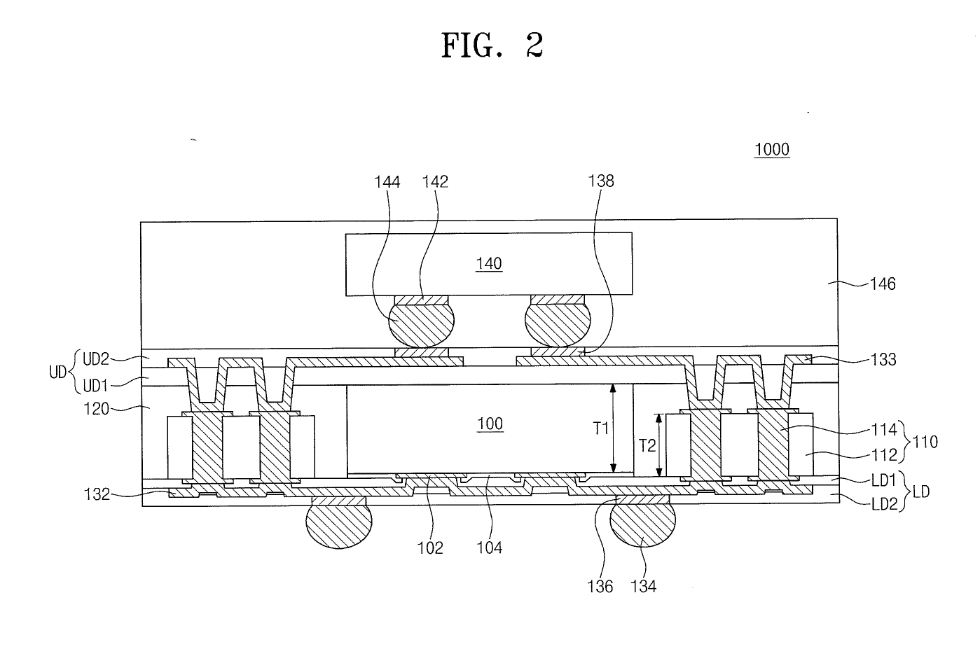

Referring to FIG. 1, a plurality of lower semiconductor chips 100 may be attached onto a support substrate 10. The lower semiconductor chips 100 may be arranged along a first direction X and also along a second direction Y crossing the first direction X. As seen in FIG. 1, directions X and Y may be substantially orthogonal to one another. A plurality of connection members 110 may be disposed at opposite sides of the lower semiconductor chips 100 along the first direction X. In detail, one or more connection members 110 may be provided between the lower semiconductor chips 100 that are adjacently arranged along the first direction X. In an exemplary embodiment as illustrated in FIG. 1, two connection members 110 may be interposed between adjacent lower semiconductor chips 100. A plurality of upper semiconductor chips 140 as seen in FIG. 2 may be mounted on the lower semiconductor chips 100. After removal of the support substrate 10, a singulation or dicing process may be performed to form a plurality of unit semiconductor packages 1000 and 2000 as seen in FIGS. 1, 2 and 3. Each of the unit semiconductor packages 1000 and 2000 may comprise the lower semiconductor chip 100, the upper semiconductor chip 140, and the connection member 110 that comprises a part of the electrical connection between the lower semiconductor chip 100 and the upper semiconductor chip 140.

Semiconductor packages according to an embodiment of the invention concepts will be discussed in detail with reference to FIG. 2.

FIG. 2 illustrates a semiconductor package according to an exemplary embodiment of the present inventive concept.

Referring to FIG. 2, a semiconductor package 1000 may comprise the lower semiconductor chip 100, the connection member 110, a lower molding layer 120, and the upper semiconductor chip 140. A lower chip pad 102 and a resist layer 104 may be provided on a bottom surface of the lower semiconductor chip 100. The resist layer 104 may expose the lower chip pad 102 but otherwise cover the bottom surface of the lower semiconductor chip 100.

The connection member 110 may be disposed spaced apart from one side of the lower semiconductor chip 100. The connection member 110 may comprise a body portion 112 and a conductive connector 114. The conductive connector 114 may penetrate through the body portion 112 and then extend outward to partially cover top and bottom surfaces thereof. A plurality of conductive connectors 114 may be provided, and the plurality of conductive connectors 114 may be electrically connected to each other. The lower semiconductor chip 100 may have a thickness T1 that is greater than a thickness T2 of the connection member 110, as seen in FIG. 2.

The lower molding layer 120 may encapsulate the lower semiconductor chip 100 and the connection member 110. In detail, the lower molding layer 120 may cover a side surface along a first side of the lower semiconductor chip 100 and side and top surfaces of the connection member 110. The lower molding layer 120 may further cover a top end of the conductive connector 114 which is disposed on the top surface of the body portion 112. A top surface of the lower semiconductor chip 100 may be exposed from the lower molding layer 120. As such, the top surface of the lower semiconductor chip 100 may have a level substantially the same as a top surface of the lower molding layer 120. The top surface of the lower molding layer 120 is higher than a top surface of the connection member 110. A bottom surface of the lower molding layer 120 may have a level substantially the same as a bottom surface of the connection member 110. The lower molding layer 120 may have a thickness substantially the same as the thickness T1 of the lower semiconductor chip 100.

A lower insulating layer LD may cover the bottom surface of the lower molding layer 120 and a bottom surface of the resist layer 104. The lower insulating layer LD may include a first lower insulating layer LD1 and a second lower insulating layer LD2. In detail, the first lower insulating layer LD1 may be disposed to cover the resist layer 104 and the lower molding layer 120. The second lower insulating layer LD2 may cover the first lower insulating layer LD1. At least one of the first and second lower insulating layers LD1 and LD2, respectively, may include an inorganic dielectric layer such as a silicon oxide layer, a silicon nitride layer and silicon oxynitride layer, or a polymeric layer such as a polyimide-based organic layer.

A lower electric line 132 may be interposed between the first and second lower insulating layers LD1 and LD2. The lower electric line 132 may penetrate the first lower insulating layer LD1 to contact both the lower chip pad 102 and a bottom end of the conductive connector 114 which is disposed on the bottom surface of the body portion 112. The lower electric line 132 may then be electrically connected to the lower chip pad 102 and the conductive connector 114.

An external terminal 134 may be disposed on a bottom surface of the second lower insulating layer LD2. The external terminal 134 may be located between the lower semiconductor chip 100 and the connection member 110 as seen in FIG. 2, A terminal pad 136 may be disposed between the external terminal 134 and the lower electric line 132. The terminal pad 136 may contact the lower electric line 132 and the external terminal 134 such that the external terminal 134 may be electrically connected to the lower electric line 132.

An upper insulating layer UD may be disposed on the top surface of the lower molding layer 120. The upper insulating layer UD may include a first upper insulating layer UD1 and a second upper insulating layer UD2. In detail, the first upper insulating layer UD1 may cover the top surfaces of the lower semiconductor chip 100 and the lower molding layer 120. The second upper insulating layer UD2 may cover the first upper insulating layer UD1. The first and second upper insulating layers UD1 and UD2, respectively, may include an inorganic dielectric layer such as a silicon oxide layer, a silicon nitride layer and silicon oxynitride layer, or a polymeric layer such as a polyimide-based organic layer. The first lower insulating layer LD1 and the first upper insulating layer UD1 may be formed of the same material, and the second lower insulating layer LD2 and the second upper insulating layer UD2 may be formed of the same material.

An upper electric line 133 may be interposed between the first and second upper insulating layers UD1 and UD2. The upper electric line 133 may penetrate the first upper insulating layer UD1 to contact the top end of the conductive connector 114 which is disposed on the top surface of the body portion 112. The upper electric line 133 may be connected to a single connection member 110 by contact with conductive connector 114. For example, when two or more upper electric lines 133 and two or more connection members 110 are provided, each upper electric line 133 may be electrically connected to an associated connection member 110, respectively, and the upper electric lines 133 may be electrically insulated from each other.

An upper semiconductor chip 140 may be mounted on the second upper insulating layer UD2. An upper chip pad 142 may be disposed on a bottom surface of the upper semiconductor chip 140, and a solder ball 144 may be attached onto a lower surface of the upper chip pad 142. The solder ball 144 may be disposed on a top surface of the second upper insulating layer UD2. A connection pad 138 may be interposed between the solder ball 144 and the upper electric line 133. The connection pad 138 may contact both the upper electric line 133 and the solder ball 144 such that the upper electric line 133 may be electrically connected to the solder ball 144. A plurality of the connection pads 138 may be coupled to, one-to-one, to a plurality of the upper electric lines 133. Alternatively, the plurality of the connection pads 138 may be commonly coupled to a single upper electric line 133.

An upper molding layer 146 may be disposed on the upper insulating layer UD. The upper molding layer 146 may cover the upper semiconductor chip 140.

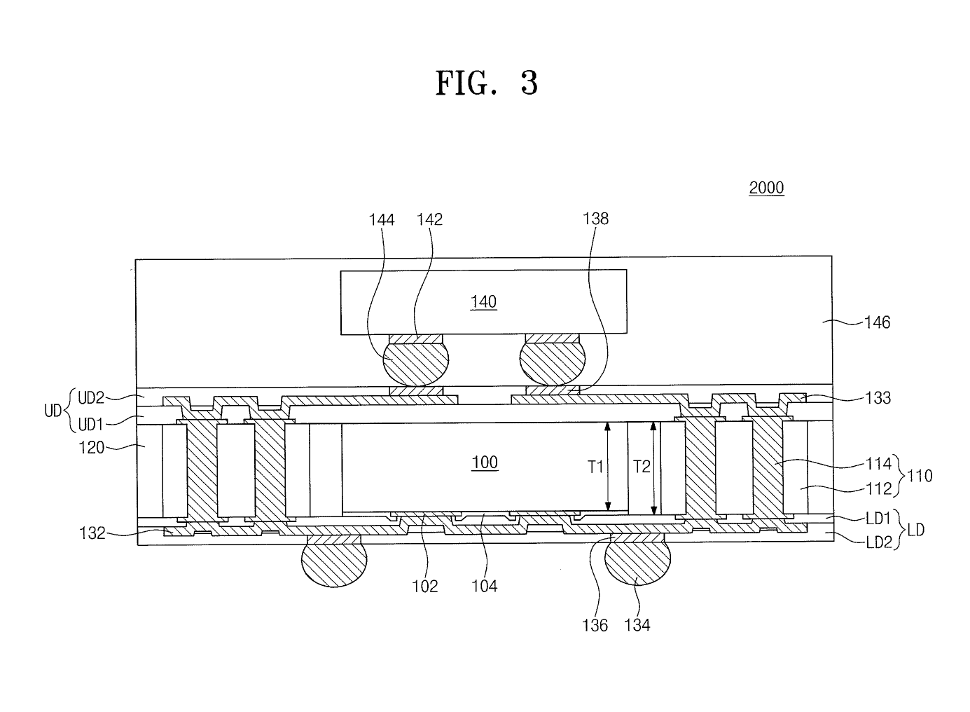

FIG. 3 illustrates a cross-sectional view of a semiconductor package according to another exemplary embodiment of the present inventive concept. In the description of the embodiment of FIG. 3, the description of features that are the same as or similar to those in FIG. 2 may be omitted in order to avoid repetition, and previously described elements may be identified by identical reference numbers.

Referring to FIG. 3, a semiconductor package 2000 may comprise the lower semiconductor chip 100, the connection member 110, the lower molding layer 120, and the upper semiconductor chip 140. The lower chip pad 102 and the resist layer 104 may be disposed on the bottom surface of the lower semiconductor chip 100 as shown in FIG. 2.

The connection member 110 may be disposed spaced apart from one side of the lower semiconductor chip 100. The connection member 110 may comprise the body portion 112 and the conductive connector 114. In this embodiment, however, the lower semiconductor chip 100 may have a thickness T1 that is substantially the same as the thickness T2 of the connection member 110.

The lower molding layer 120 may cover the lower semiconductor chip 100 and the connection member 110. In detail, the lower molding layer 120 may cover a side surface along a first side of the lower semiconductor chip 100 and the adjacent side surface of the connection member 110. The top surface of the lower semiconductor chip 100 may be exposed from the lower molding layer 120. The top end of the conductive connector 114 may be disposed on the top surface of the body portion 112 and exposed from the lower molding layer 120. As such, the top surface of the lower semiconductor chip 100 and the top surface of the connection member 110 may each have a level substantially the same as the top surface of the lower molding layer 120.

The lower insulating layer LD may be provided to cover the bottom surfaces of the lower molding layer 120 and the resist layer 104. The lower insulating layer LD may include the first lower insulating layer LD1 and the second lower insulating layer LD2. The lower electric line 132 may be interposed between the first and second lower insulating layers LD1 and LD2. The lower electric line 132 may contact the bottom end of the conductive connector 114 which is disposed on the connection member 110. The external terminal 134 may be disposed on the bottom surface of the second lower insulating layer LD2. The terminal pad 136 may be disposed between the external terminal 134 and the lower electric line 132. The terminal pad 136 may contact both the lower electric line 132 and the external terminal 134 such that the external terminal 134 may be electrically connected to the lower electric line 132.

The upper insulating layer UD may be disposed on the top surface of the lower molding layer 120. The upper insulating layer UD may include the first upper insulating layer UD1 and the second upper insulating layer UD2. In detail, the first upper insulating layer UD1 may cover the top surfaces of the lower semiconductor chip 100 and the connection member 110. The second upper insulating layer UD2 may cover the first upper insulating layer UD1. The upper electric line 133 may be interposed between the first and second upper insulating layers UD1 and UD2. The upper electric line 133 may contact the top end of the conductive connector 114 which is disposed on the top surface of the connection member 110.

The upper semiconductor chip 140 may be mounted on the second upper insulating layer UD2. The upper chip pad 142 may be disposed on the bottom surface of the upper semiconductor chip 140, and the solder ball 144 may be attached onto a lower surface of the upper chip pad 142. The solder ball 144 may be disposed on the top surface of the second upper insulating layer UD2. The connection pad 138 may be disposed between the solder ball 144 and the upper electric line 133. The upper molding layer 146 may be provided on the upper insulating layer UD. The upper molding layer 146 may cover the upper semiconductor chip 140.

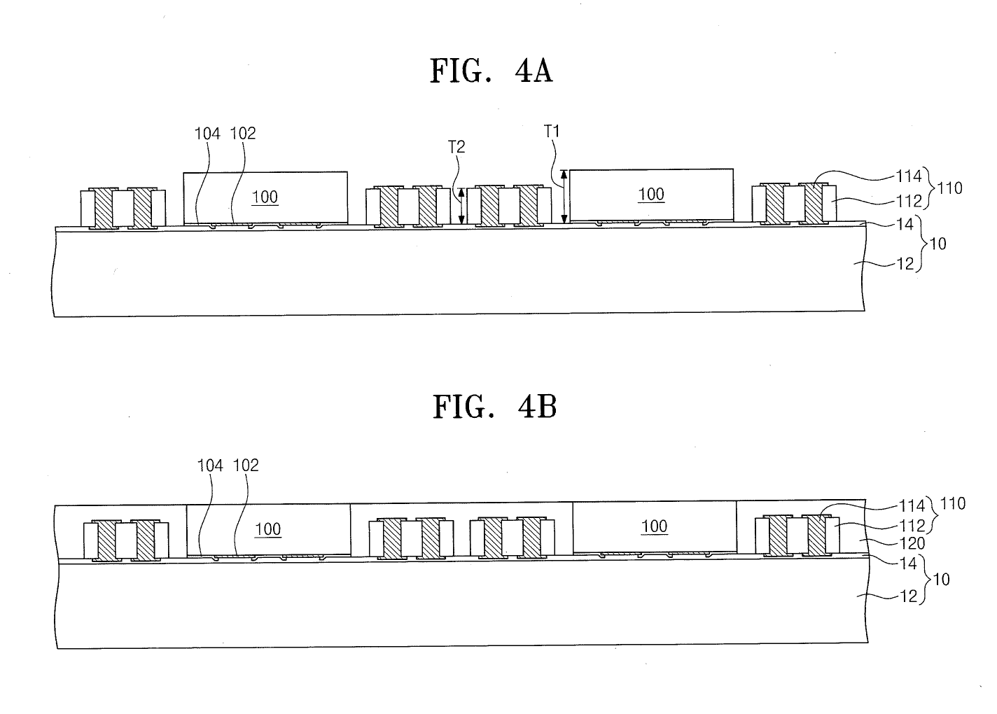

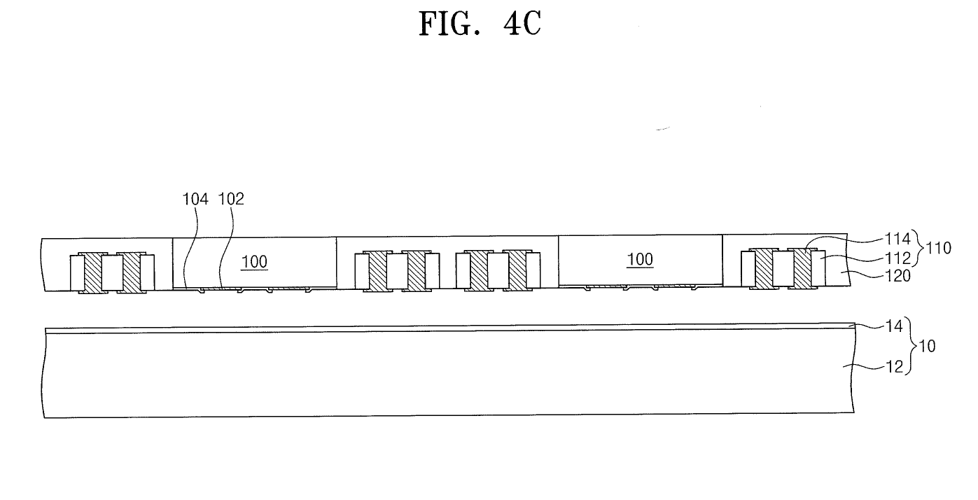

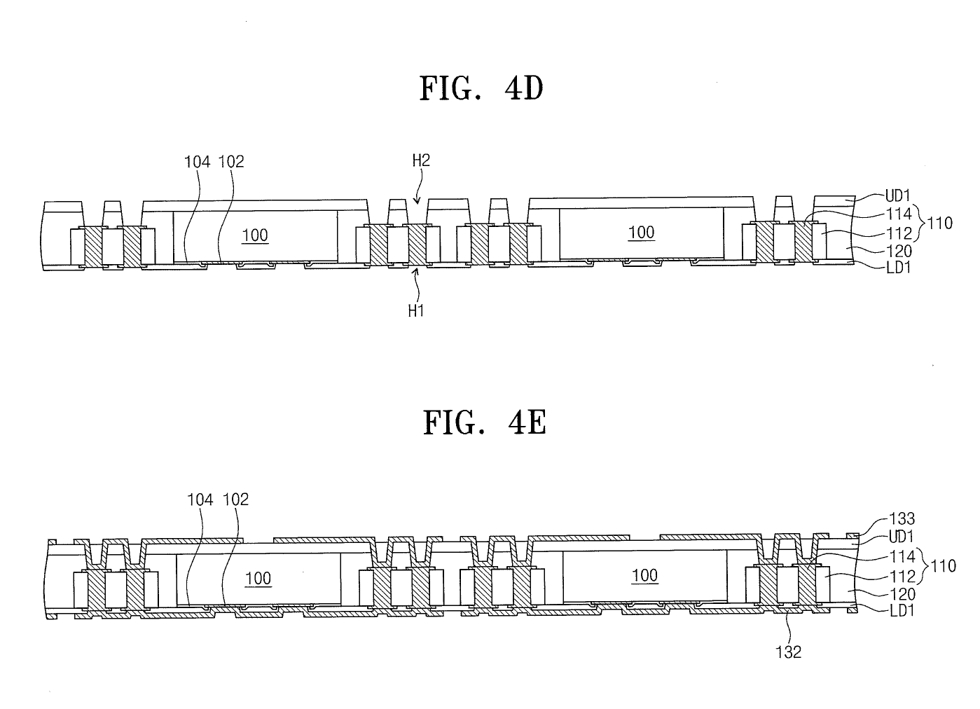

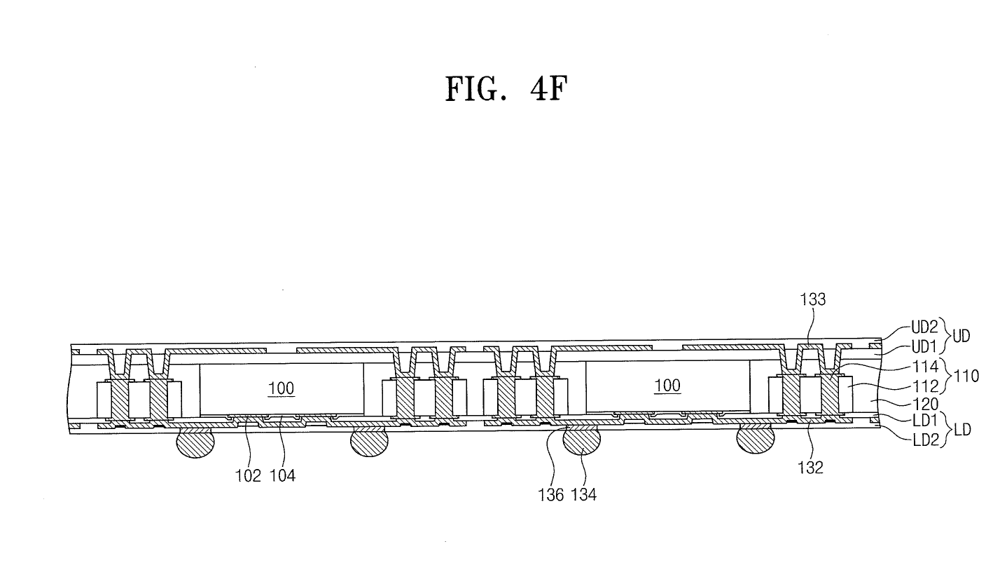

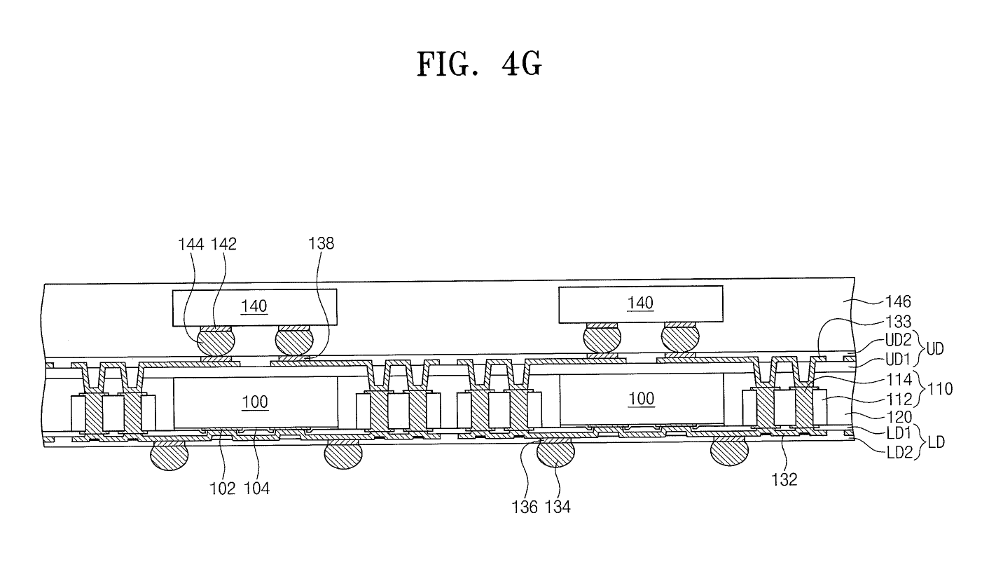

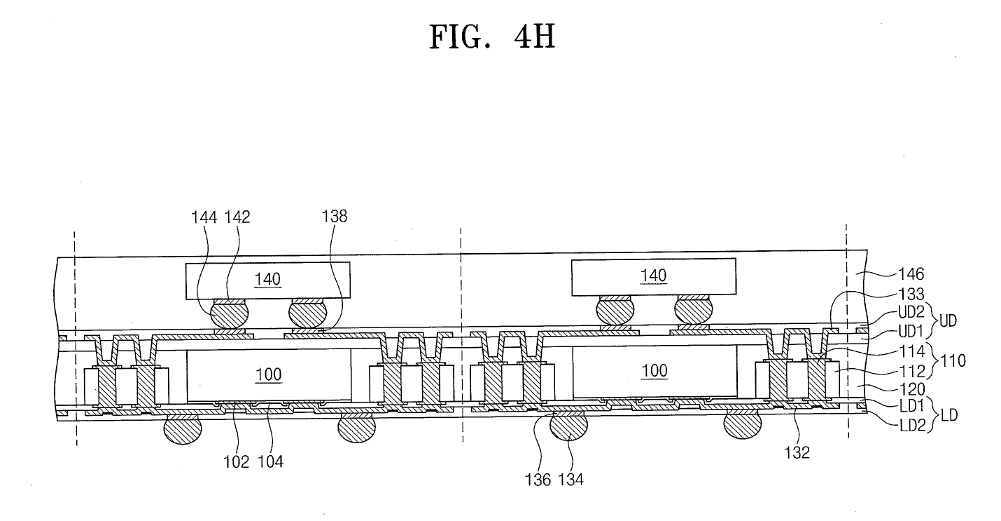

FIGS. 4A to 4H illustrate cross-sectional views of a method for fabricating a semiconductor package according to an exemplary embodiment of the present inventive concept.

Referring to FIG. 4A, a support substrate 10 may be provided. The support substrate 10 may include a base 12 and a separation film 14. The base 12 may be a carrier or a subsidiary frame on a carrier. The base 12 may be formed of various materials such as glass, plastic, metal, and so forth. The separation film 14 may be formed on the base 12 so as to conform to the base 12. The separation film 14 may be a double-sided adhesive tape or a glue layer. In the case where the separation film 14 is a double-sided adhesive tape, the separation film 14 may be attached onto the base 12 by a lamination process using vacuum. In the case where the separation film 14 is a glue layer, an adhesive material may be coated to form the separation film 14.

A lower semiconductor chip 100 may be disposed on the separation film 14. A bottom surface of the lower semiconductor chip 100 may be bonded to the separation film 14. A lower chip pad 102 and a resist layer 104 may be disposed on the bottom surface of the lower semiconductor chip 100. The resist layer 104 may expose the lower chip pad 102 but otherwise cover the bottom surface of the lower semiconductor chip 100 so as to conform to that bottom surface.

A connection member 110 may also be disposed on the separation film 14. A bottom surface of the connection member 110 may be bonded to the separation film 14. The connection member 110 may include a body portion 112 and a conductive connector 114. A copper clad laminate (CCL) may be used as the body portion 112. The copper clad laminate may be mechanically drilled to form a cavity through the body portion 112, and then the cavity may be filled with a conductive material to form the conductive connector 114. A plurality of the conductive connectors 114 may be formed in the body portion 112.

The lower semiconductor chip 100 may have a thickness T1 greater than a thickness T2 of the connection member 110 (FIG. 2 and FIG. 4A). Alternatively, as shown in FIG. 3, the thickness T1 of the lower semiconductor chip 100 may be substantially the same as the thickness T2 of the connection member 110.

Referring back to FIG. 1, a plurality of the lower semiconductor chips 100 may be arranged along a first direction X and also along a second direction Y that is substantially perpendicular to the first direction X. The connection member 110 may be disposed between the lower semiconductor chips 100 that are arranged along the first direction X. A plurality of the connection members 110 may be arranged along the first direction X and also along the second direction Y. One or more connection members 110 may be disposed between the lower semiconductor chips 100 that are arranged along the first direction X, but not between the lower semiconductor chips 100 that are arranged along the Y direction.

Referring to FIG. 4B, a lower molding layer 120 may be formed on the separation film 14. The lower molding layer 120 may cover the lower semiconductor chips 100 and the connection members 110. In detail, the lower molding layer 120 may cover a side surface of the lower semiconductor chip 100 and side and top surfaces of the connection member 110. A top surface of the lower semiconductor chip 100 may be exposed from a top surface of the lower molding layer 120 if the top surface of the lower semiconductor chip 100 has a level substantially the same as a top surface of the lower molding layer 120.

Alternatively, as shown in FIG. 3, the lower molding layer 120 may cover the side surface of the lower semiconductor chip 100 and the side surface of the connection member 110. The top surfaces of both the lower semiconductor chip 100 and the connection member 110 may be exposed from the lower molding layer 120.

Referring back to FIG. 4B, the lower molding layer 120 may be selectively formed to fill an area in which the connection member 110 is disposed between the lower semiconductor chips 100. It therefore may be possible to skip performing a planarization process for reducing the step height, i.e., a difference of level between the top surface of the lower molding layer 120 and the top surface of the lower semiconductor chip 100. The lower molding layer 120 may be formed of epoxy-based material, for example, EMC.

In an exemplary embodiment, the lower semiconductor chip 100 may have a thickness substantially the same as or greater than that of the connection member 110 such that it may be possible to omit a planarization process for exposing a top surface of the lower semiconductor chip 100 and/or for reducing the thickness of the lower molding layer 120. As a result, it may be possible to prevent the problems (e.g., deterioration of electrical characteristics) caused by foreign substances which can be generated during a planarization process along the top surface of the semiconductor chip and/or in the semiconductor package.

When the lower molding layer 120 covers the top of the lower semiconductor chip 100, the lower molding layer 120 may induce warpage of the semiconductor package. In such a case, after the support substrate 10 is removed, the lower semiconductor chip 100 and the lower molding layer 120 are not supported by any layer. Because the lower molding layer 120 and the lower semiconductor chip 100 are formed of different materials whose characteristics are not physically symmetrical, the semiconductor package may suffer from warpage. In an exemplary embodiment, since the lower semiconductor chip 100 has a thickness greater than or identical to that of the connection member 110, the lower molding layer 120 may not cover the top surface of the lower semiconductor chip 100 and thus this fabrication step may prevent or reduce warpage of the semiconductor package.

Referring to FIG. 4C, the separation film 14 may be selectively removed to separate the support substrate 10 from the lower semiconductor chip 100, the connection member 110 and the lower molding layer 120. If the separation film 14 is a double-sided adhesive tape, the application of heat, for example at a temperature of about 170° C. or above, may be used to weaken the adhesive strength of the adhesive tape to facilitate the separation step. Alternatively, if the base 12 of the support substrate 10 is formed of glass, a bottom surface of the base 14 may be irradiated with ultraviolet light to weaken the adhesive strength of the adhesive tape. Alternatively, a chemical may be used to dissolve the separation film 14. A curing or chemical treatment step may also be used to selectively remove the separation film 14. The removal of the separation film 14 may expose the lower chip pad 102, the lower molding layer 120 and the bottom surface of the connection member 110. Since the bottom surface of the connection member 110 is thus exposed, a bottom end of the conductive connector 114 may also be exposed from the bottom surface of the body portion 112.

Referring to FIG. 4D, a first lower insulating layer LD1 may be formed on a bottom surface of the lower molding layer 120, and a first upper insulating layer UD1 may be formed on a top surface of the lower molding layer 120. The first lower insulating layer LD1 may contact the lower chip pad 102 and the bottom end of the conductive connector 114 which is disposed on the bottom surface of the body portion 112. The first upper insulating layer UD1 may contact the top surfaces of the lower semiconductor chip 100 and the lower molding layer 120. The first lower insulating layer LD1 and the first upper insulating layer UD1 may be formed by, for example, at least one of the following processes: spin coating, PVD, CVD, sputtering, ALD, and printing processes. The first lower and the first upper insulating layers LD1 and UD1, respectively, may be formed of an inorganic dielectric layer such as a silicon oxide layer, a silicon nitride layer and silicon oxynitride layer, or a polymeric layer such as a polyimide-based organic layer.

The first lower insulating layer LD1 may be patterned to form a first via hole H1. The first via hole H1 may expose the conductive connector 114 exposed on the bottom surface of the body portion 112 and further expose the lower chip pad 102. The first upper insulating layer UD1 and the lower molding layer 120 may also be patterned to form a second via hole H2. The second via hole H2 may expose the top end of the conductive connector 114 which is disposed on the top surface of the body portion 112. The second via hole H2 may further expose side surfaces of the first upper insulating layer UD1 and the lower molding layer 120. The first and second via holes H1 and H2, respectively, may be formed by, for example, one of the following processes: a laser process, a photolithography process, and an etch process.

Referring to FIG. 4E, a lower electric line 132 may be formed on the first lower insulating layer LD1. In detail, the lower electric line 132 may be formed by depositing a wiring layer (not shown) on the first lower insulating layer LD1 and then patterning the wiring layer to form the lower electric line 132. The lower electric line 132 may cover a surface of the first lower insulating layer LD1 and contact the lower chip pad 102 and the bottom end of the conductive connector 114 which is disposed on the bottom surface of the body portion 112. An upper electric line 133 may be formed on the first upper insulating layer UD1. The upper electric line 133 may cover a surface of the first upper insulating layer UD1 and an inner side surface of the second via hole H2 (FIG. 4D), and also contact the top end of the conductive connector 114 which is disposed on the top surface of the body portion 112. After forming the upper electric line 133, the second via hole H2 may be filled with a material substantially the same as the first upper insulating layer UD1, so that an insulating layer filling the second hole H2 may have a top surface level substantially the same as that of the first upper layer UD1. The lower and upper electric lines 132 and 133, respectively, may include a conductive material, for example, copper.

Referring to FIG. 4F, a second lower insulating layer LD2 may be formed on the first lower insulating layer LD1, and a second upper insulating layer UD2 may be formed on the first upper insulating layer UD1. The second lower insulating layer LD2 may cover the lower electric line 132, and the second upper insulating layer UD2 may cover the upper electric line 133, respectively. The second lower and the second upper insulating layers LD2 and UD2, respectively, may be formed by, for example, at least one of the following processes: spin coating, PVD, CVD, sputtering, ALD, and printing processes. The second lower and the second upper insulating layers LD2 and UD2, respectively, may be formed of an inorganic dielectric layer such as a silicon oxide layer, a silicon nitride layer and silicon oxynitride layer, or a polymeric layer such as a polyimide-based organic layer. The first and second lower insulating layers LD1 and LD2 together may constitute a lower insulating layer LD, and the first and second upper insulating layers UD1 and UD2 together may constitute an upper insulating layer UD.

A terminal pad 136 may be formed on the second lower insulating layer LD2. The terminal pad 136 may be disposed between the lower semiconductor chip 100 and the connection member 110. The terminal pad 136 may be electrically connected to the lower electric line 132. An external terminal 134 may be formed on the terminal pad 136.

Referring to FIG. 4G, an upper semiconductor chip 140 may disposed on the second upper insulating layer UD2. An upper chip pad 142 may be disposed on a bottom surface of the upper semiconductor chip 140, and a solder ball 144 may be attached onto the upper chip pad 142. The solder ball 144 may be coupled to a connection pad 138 disposed on the upper electric line 133. The connection pad 138 may be electrically connected to the upper electric line 133. The upper semiconductor chip 140 may therefore be electrically connected to the lower semiconductor chip 100 by the lower electric line 132 and the connection member 110 contacting the upper electric line 133. Also as seen in FIG. 4G, an upper molding layer 146 may be formed on the second upper insulating layer UD2. The upper molding layer 146 may cover the upper semiconductor chip 140. The upper molding layer 146 may be formed of a material substantially the same as the material of the lower molding layer 120. A plurality of the upper semiconductor chips 140 may be disposed on the second upper insulating layer UD2. Semiconductor devices such as passive elements (not shown in FIG. 4G) may be mounted on the second upper insulating layer UD2.

Referring to FIG. 4H and FIG. 2, a singulation or dicing process may be performed to cut the upper molding layer 146, the upper insulation layer UD, the lower molding layer 120 and the lower insulating layer LD so as to divide the structure of FIG. 4H (along the dotted lines) into a plurality of unit semiconductor packages 1000 as shown in FIG. 2. The semiconductor package 1000 may be a fan-out wafer-level package.

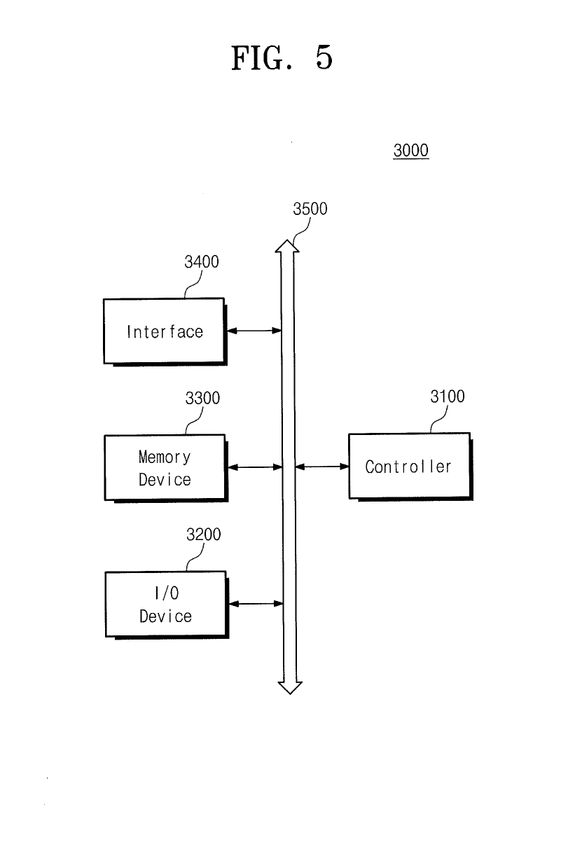

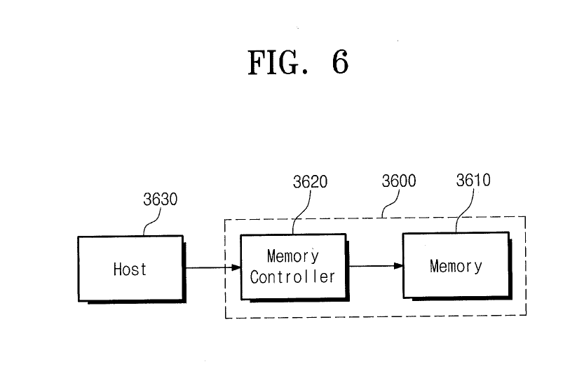

FIG. 5 illustrates a block diagram of an example of an electronic device including a semiconductor package according to an exemplary embodiment of the inventive concepts. FIG. 6 illustrates a block diagram of an example of a memory system including a semiconductor package according to an exemplary embodiment of the present inventive concept.

Referring to FIG. 5, an electronic system 3000 may include a controller 3100, an input/output (I/O) device 3200, and a memory device 3300. The controller 3100, the I/O device 3200, and the memory device 3300 may be connected to each other through a bus 3500. The bus 3500 may be a transfer path for data. For example, the controller 3100 may include at least one of a microprocessor, a digital signal processor, and a microcontroller, or at least one logic device capable of performing the same functions as these devices. The controller 3100 and the memory device 3300 may include semiconductor packages according to exemplary embodiments of the inventive concepts. The I/O device 3200 may include at least one of a keypad, a keyboard, a display device, and the like. The memory device 3300 may store data. The memory device 3300 may store data and/or commands executed by the controller 3100. The memory device 3300 may include a volatile memory device and/or a nonvolatile memory device. The memory device 3300 may include a flash memory. For example, the flash memory may be mounted in an information processing system such as in a mobile unit or a desktop computer. The flash memory may be constituted by a SSD (solid state disk). In this case, the electronic system 3000 may be capable of reliably storing a mass of data in the flash memory system. The electronic system 3000 may further include an interface 3400 for transmitting data to a communication network or for receiving data from the communication network. The interface 3400 may be in the form of a wire/wireless interface. For example, the interface 3400 may include an antenna or a wire/wireless transceiver. In addition, although not illustrated in the drawings, the electronic system 3000 may further include, e.g., an application chipset, a CIS (camera image processor), and an input-output device.

The electronic system 3000 may constitute or be a part of a mobile system, a personal computer, an industrial computer, or a logical system for performing various functions. For example, the mobile system may be a PDA (personal digital assistant), a portable computer, a web tablet, a mobile phone, a wireless phone, a laptop computer, a memory card, a digital music system, or an information transmitting/receiving system. In the case where the electronic system 3000 is an equipment capable of performing a wireless communication, the electronic system 3000 may be used via a communication interface protocol of a third generation communication system, such as CDMA, GSM, NADC, E-TDMA, WCDAM, or CDMA2000.

Referring to FIG. 6, a memory card 3600 may include a nonvolatile memory device 3610 and a memory controller 3620. The nonvolatile memory device 3610 and the memory controller 3620 may be capable of storing data or reading stored data. The nonvolatile memory device 3610 may include a nonvolatile memory device to which a semiconductor package according to an exemplary embodiment of the inventive concepts is applied. The memory controller 3620 may control the nonvolatile memory device 3610 so as to read stored data or to store data in response to the reading/writing request of the host 3630.

According to embodiments of the present invention, the semiconductor package may include a semiconductor chip having a thickness substantially the same as, or a thickness greater than, that of the connection member. As previously discussed, this may prevent warpage of the wafer-level semiconductor package.

Although the present invention has been described in connection with embodiments of the present invention illustrated in the accompanying drawings, it is not limited thereto. It will be apparent to those skilled in the art that various substitution, modifications and changes may be thereto without departing from the scope and spirit of the invention.

What is claimed is:

1. A semiconductor package comprising:
a first semiconductor chip;
a connection member disposed at one side of the first semiconductor chip;
a first insulating layer covering bottom surfaces of the first semiconductor chip and the connection, member;
a first molding layer that is disposed on the first insulating layer and covers a side surface of the first semiconductor chip and a top surface and opposite side surfaces of the connection member;
a first electric line disposed on the first insulating layer and electrically connected to the first semiconductor chip and the connection member; and
an external terminal disposed on the first insulating layer and electrically connected to the first electric line.

2. The semiconductor package of claim 1, wherein a top surface of the first semiconductor chip is exposed from the first molding layer.

3. The semiconductor package of claim 2, wherein the top surface of the first semiconductor chip has a level substantially the same as a top surface of the first molding layer.

4. The semiconductor package of claim 1, wherein the connection member comprises a body portion and a conductive connector penetrating the body portion,
wherein the conductive connector contacts the first electric line.

5. The semiconductor package of claim 1, further comprising:
a first chip pad disposed on the bottom surface of the first semiconductor chip; and
a resist layer covering the bottom surface of the first semiconductor chip and exposing the first chip pad,
wherein the first chip pad contacts the first electric line.

6. The semiconductor package of claim 1, further comprising:
a second insulating layer disposed on a top surface of the first semiconductor chip; and
a second electric line disposed in the second insulating layer and electrically connected to the connection member,
wherein the second insulating layer contacts top surfaces of the first semiconductor chip and the first molding layer.

7. The semiconductor package of claim 6, further comprising:
a second semiconductor chip disposed on the second insulating layer;
a second chip pad disposed on a bottom surface of the second semiconductor chip;
a solder ball adhered to the second chip pad and electrically connected to the second electric line; and
a second molding layer that is disposed on the second insulating layer and covers the second semiconductor chip.

8. The semiconductor package of claim 1, wherein the external terminal is disposed between the first semiconductor chip and the connection member.

9. A semiconductor package comprising:
a lower semiconductor chip;
a connection member disposed at one side of the lower semiconductor chip;
a lower insulating layer covering bottom surfaces of the lower semiconductor chip and the connection member;
a lower molding layer that is disposed on the lower insulating layer and covers the connection member;
a lower electric line disposed in the lower insulating layer and electrically connected to the lower semiconductor chip and the connection member;
an upper insulating layer disposed on the lower molding layer and contacting a top surface of the lower semiconductor chip;
an upper electric line disposed in the upper insulating layer and electrically connected to the connection member; and
an external terminal disposed on the lower insulating layer and electrically connected to the lower electric line.

10. The semiconductor package of claim 9, wherein the lower semiconductor chip and the connection member have the same thickness such that a top surface of the connection member contacts the upper insulating layer.

11. The semiconductor package of claim 9, wherein the lower semiconductor chip has a thickness greater than that of the connection member.

12. The semiconductor package of claim 11, wherein the lower molding layer is interposed between the upper insulating layer and the connection member, and
wherein the lower molding layer on the connection member contacts a bottom surface of the upper insulating layer and a top surface of the connection member.

13. The semiconductor package of claim 11, wherein the lower molding layer has a thickness substantially the same as that of the lower semiconductor chip.

14. The semiconductor package of claim 9, wherein the lower semiconductor chip has a thickness greater than that of the connection member such that a top surface of the molding layer is higher than a top surface of the connection member.

15. The semiconductor package of claim 9, further comprising:
an upper semiconductor chip mounted on the upper insulating layer; and
an upper molding layer that is disposed on the upper insulating layer and covers the upper semiconductor chip.

16. A semiconductor package comprising:
a lower semiconductor chip;
a connection member at one side of the lower semiconductor chip;
a lower insulating layer covering bottom surfaces of the lower semiconductor chip and the connection member;
a lower molding layer on the lower insulating layer and covers the connection member;
a lower electric line in the lower insulating layer and electrically connected to the lower semiconductor chip and the connection member;
an upper insulating layer on a top surface of the lower semiconductor chip;
an upper electric line in the upper insulating layer and electrically connected to the connection member;
an external terminal on the lower insulating layer and electrically connected to the lower electric line; and
an upper semiconductor chip electrically connected to the upper electric line to provide an electrical connection between the upper and the lower semiconductor chips via the connection member.

17. The semiconductor package of claim 16, wherein the lower semiconductor chip and the connection member have the same thickness such that a top surface of the connection member contacts the upper insulating layer.

18. The semiconductor package of claim 16, wherein the lower semiconductor chip has a thickness greater than that of the connection member.

19. The semiconductor package of claim 9, wherein the connection member comprises a body portion and a conductive connector disposed in the body portion,
wherein the conductive connector is electrically connected to the lower electric line and the upper electric line.

20. The semiconductor package of claim 19, wherein the body portion is consisting of a copper clad laminate.
